(19) United States
(12) Patent Application Publication
(10) Pub. No.: US 2026/0314169 A1
(43) Pub. Date: Oct. 8, 2026

(54) LIGHT-EMITTING DEVICE AND DISPLAY PANEL

(71) Applicants: Yunnan Invensight Optoelectronics Technology Co., Ltd., Kunming, Yunnan (CN); BOE TECHNOLOGY GROUP CO., LTD., Beijing (CN); Beijing BOE Technology Development Co., Ltd., Beijing (CN)

(72) Inventors: Li SUN, Beijing (CN); Yinhu HUANG, Beijing (CN)

(73) Assignees: Yunnan Invensight Optoelectronics Technology Co., Ltd., Kunming, Yunnan (CN); BOE TECHNOLOGY GROUP CO., LTD., Beijing (CN); Beijing BOE Technology Development Co., Ltd., Beijing (CN)

(21) Appl. No.: 19/481,187

(22) PCT Filed: May 17, 2023
(86) PCT No.: PCT/CN2023/094883

§ 371 Date: Nov. 4, 2025

(51) Int. Cl. H10K 50/13

(52) U.S. Cl. CPC H10K 50/13

(57) ABSTRACT

A light-emitting device includes a substrate, a first electrode, a light-emitting unit, and a second electrode; where the light-emitting unit includes a plurality of sub-light-emitting units stacked in a direction perpendicular to the substrate, and a charge generation layer located between the adjacent sub-light-emitting units; among the plurality of sub-light-emitting units, the sub-light-emitting unit proximate to the second electrode is a white light-emitting unit.

### TECHNICAL FIELD

The present disclosure relates to the field of display technologies, and in particular, to a light-emitting device and a display panel.

### BACKGROUND

In some OLED (Organic Light-Emitting Diodes) display screens, a pixel feature is that a first electrode layer or a layer below it in the pixel light-emitting region is not on the same plane. That is, they are in different regions, on different planes, and different regions have height differences. When a film is formed by evaporation deposition, the thickness of a multi-film layer structure deposited on the first electrode layer is inconsistent in different regions, especially in a transition region between two planes. Thus, devices with different structural thicknesses are formed in a plane region and the transition region, and normal devices and abnormal devices are formed.

In the prior art, white light devices are usually formed by connecting two or more light-emitting units with different colors in series. In this white light device, the thickness difference is great between the light-emitting device close to a first electrode and the light-emitting unit away from the first electrode in an abnormal region, which affects the light-emitting quality of the white light device.

It should be noted that the information disclosed in the above background section is only used to enhance understanding the background of this disclosure, and therefore may include information that does not constitute the prior art known to those skilled in the art.

### SUMMARY

The present disclosure is directed to provide a light-emitting device and a display panel, which facilitate to mitigating the problem of a large light-emitting quality difference when the driving voltage of the light-emitting device changes from low to high.

In order to achieve the purpose of the invention, the present disclosure adopts the following technical solutions.

According to a first aspect of the present disclosure, there is provided a light-emitting device, including a substrate, and a first electrode, a light-emitting unit and a second electrode stacked in a direction away from the substrate;

where, the light-emitting unit includes a plurality of light-emitting sub-units stacked in a direction perpendicular to the substrate and a charge generation layer located between adjacent light-emitting sub-units; and

among the plurality of light-emitting sub-units, the light-emitting sub-unit close to the second electrode is a white light-emitting unit.

In an exemplary embodiment of the present disclosure, the plurality of light-emitting sub-units at least include a second light-emitting unit and a first light-emitting unit stacked in the direction away from the substrate, and the first light-emitting unit is the white light-emitting unit.

In an exemplary embodiment of the present disclosure, the first light-emitting unit includes a first light-emitting layer, and the first light-emitting layer includes a first light-emitting sub-layer and a second light-emitting sub-layer stacked in the direction away from the substrate;

one of the first light-emitting sub-layer and the second light-emitting sub-layer is a blue light-emitting layer and the other one is a yellow light-emitting layer.

In an exemplary embodiment of the present disclosure, the first light-emitting sub-layer is the blue light-emitting layer, the second light-emitting sub-layer is the yellow light-emitting layer, and a material of the first light-emitting sub-layer is the phosphorescent light-emitting material; or

the first light-emitting sub-layer is the yellow light-emitting layer, the second light-emitting sub-layer is the blue light-emitting layer, and a material of the second light-emitting sub-layer is the fluorescent light-emitting material.

In an exemplary embodiment of the present disclosure, the first light-emitting layer further includes the first spacer layer, and the first spacer layer is arranged between the first light-emitting sub-layer and the second light-emitting sub-layer.

In an exemplary embodiment of the present disclosure, the second light-emitting unit includes a second light-emitting layer, the first light-emitting layer and/or the second light-emitting layer include at least one optical adjustment layer, and the optical adjustment layer is used for adjusting a light-emitting characteristic of the light-emitting unit.

In an exemplary embodiment of the present disclosure, the optical adjustment layer includes at least one of a blue light-emitting layer, a yellow light-emitting layer, a green light-emitting layer or a red light-emitting layer.

In an exemplary embodiment of the present disclosure, the first light-emitting layer further includes one optical adjustment layer, and the optical adjustment layer of the first light-emitting layer is located on a side of the second light-emitting sub-layer away from the substrate; and

the second light-emitting layer includes one optical adjustment layer, and the optical adjustment layer of the second light-emitting layer is the yellow light-emitting layer or the red light-emitting layer.

In an exemplary embodiment of the present disclosure, when the optical adjustment layer of the second light-emitting layer is the yellow light-emitting layer, the first light-emitting sub-layer is the blue light-emitting layer, the second light-emitting sub-layer is the yellow light-emitting layer, and the optical adjustment layer of the first light-emitting layer is the blue light-emitting layer.

In an exemplary embodiment of the present disclosure, when the optical adjustment layer of the second light-emitting layer is the red light-emitting layer, the first light-emitting sub-layer is the yellow light-emitting layer, the second light-emitting sub-layer is the blue light-emitting layer, and the optical adjustment layer of the first light-emitting layer is the green light-emitting layer.

In an exemplary embodiment of the present disclosure, the second light-emitting layer includes two optical adjustment layers, one of the two optical adjustment layers of the second light-emitting layer is the blue light-emitting layer and the other one is the red light-emitting layer, where the blue light-emitting layer is located on a side of the red light-emitting layer away from the substrate, and a material of the blue light-emitting layer is a fluorescent light-emitting material.

In an exemplary embodiment of the present disclosure, the first light-emitting sub-layer is the yellow light-emitting layer, the second light-emitting sub-layer is the blue light-emitting layer, and the material of the second light-emitting sub-layer is the fluorescent light-emitting material;

the first light-emitting layer further includes the first spacer layer, the first spacer layer is arranged between the first light-emitting sub-layer and the second light-emitting sub-layer; and

the second light-emitting layer further includes a second spacer layer, and the second spacer layer is arranged between the two optical adjustment layers of the second light-emitting layer.

In an exemplary embodiment of the present disclosure, the first light-emitting layer further includes one optical adjustment layer, and the optical adjustment layer of the first light-emitting layer is the red light-emitting layer located on the side of the second light-emitting sub-layer away from the substrate; and

the second light-emitting layer includes two optical adjustment layers, and the two optical adjustment layers of the second light-emitting layer both are the blue light-emitting layer.

In an exemplary embodiment of the present disclosure, the first light-emitting sub-layer is the blue light-emitting layer, and the second light-emitting sub-layer is the yellow light-emitting layer;

the first light-emitting layer further includes the first spacer layer, where the first spacer layer is arranged between the first light-emitting sub-layer and the second light-emitting sub-layer, and the optical adjustment layer of the first light-emitting unit is arranged on the side of the second light-emitting sub-layer away from the substrate.

In an exemplary embodiment of the present disclosure, when the first light-emitting sub-layer is the blue light-emitting layer and the second light-emitting sub-layer is the yellow light-emitting layer, the second light-emitting layer includes two optical adjustment layers, and the two optical adjustment layers are the blue light-emitting layer and the yellow light-emitting layer stacked in the direction away from the substrate.

In an exemplary embodiment of the present disclosure, when the first light-emitting sub-layer is the blue light-emitting layer and the second light-emitting sub-layer is the yellow light-emitting layer, the second light-emitting layer includes three optical adjustment layers;

where the three optical adjustment layers are the blue light-emitting layer, the red light-emitting layer and the green light-emitting layer stacked in the direction away from the substrate.

In an exemplary embodiment of the present disclosure, the substrate includes a first region and a second region located on a side of the first region, a thickness of the light-emitting unit located in the first region is greater than a thickness of the light-emitting unit located in the second region; and

the plurality of light-emitting sub-units at least include the second light-emitting unit and the first light-emitting unit stacked in the direction away from the substrate, a thickness of the second light-emitting unit located in the second region is less than a thickness of the second light-emitting unit located in the first region;

a thickness of the first light-emitting unit located in the second region is less than or equal to a thickness of the first light-emitting unit located in the first region; and

the thickness of the first light-emitting unit located in the second region of the substrate is greater than the thickness of the second light-emitting unit located in the second region of the substrate.

In an exemplary embodiment of the present disclosure, the thickness of the yellow light-emitting layer of the first light-emitting layer is 0.1 nm to 5 nm.

According to a second aspect of that present disclosure, there is provided a display panel including the light-emitting device according to the first aspect.

The light-emitting device provided by the present disclosure includes the plurality of light-emitting sub-units, where the light-emitting sub-unit close to the second electrode is the white light-emitting unit, so as to ensure that at least one light-emitting unit emits white light, which facilitates to mitigating the problem of the large light-emitting quality difference when the driving voltage of the light-emitting device changes from low to high.

### BRIEF DESCRIPTION OF THE DRAWINGS

The above-mentioned and other features and advantages of the present disclosure will become more apparent by describing exemplary embodiments thereof in detail with reference to the accompanying drawings.

FIG. 1 is a structural schematic diagram of the substrate according to an exemplary embodiment of the present disclosure;

FIG. 2 to FIG. 7 are structural schematic diagrams of light-emitting devices according to different exemplary embodiments of the present disclosure.

The reference numbers of main elements in the drawings are explained as follows:
10—substrate; 11—first surface; 12—second surface; 121—first sub-surface; 122—second sub-surface; 123—transition surface; 124—first region; 125—second region; 20—light-emitting device; 100—first electrode; 200—second electrode; 300—first light-emitting unit; 301—first light-emitting layer; 3011—first light-emitting sub-layer; 3012—second light-emitting sub-layer; 3013—first spacer layer; 302—first hole transport layer; 303—first electron transport layer; 400—second light-emitting unit; 401—second light-emitting layer; 402—second hole transport layer; 403—second electron transport layer; 404—second spacer layer; 500—charge generation layer; 600—optical adjustment layer.

### DETAILED DESCRIPTION

Exemplary embodiments will now be described more fully with reference to the accompanying drawings. However, exemplary embodiments can be implemented in a variety of forms and should not be construed as limited to the examples set forth herein; rather, these embodiments are provided so that the disclosure will be more comprehensive and complete and to fully convey the concepts of the exemplary embodiments to those skilled in the art. The described features, structures, or characteristics may be combined in any suitable manner in one or more embodiments. In the following description, numerous specific details are provided to give a thorough understanding of the embodiments of the present disclosure.

In the drawings, for clarity, thicknesses of regions and layers will be exaggerated. The same reference numbers in the drawings denote the same or similar structures and thus their detailed descriptions will be omitted.

The described features, structures, or characteristics may be combined in any suitable manner in one or more embodiments. In the following description, numerous specific details are provided to give a thorough understanding of the embodiments of the present disclosure. However, those skilled in the art will realize that the technical solution of the present disclosure can be practiced without one or more of the specific details, or other methods, components, materials, or the like, can be adopted. In other instance, well-known structures, material or operations are not shown or described in detail to avoid obscuring main technical idea of the present disclosure.

When a structure is “on” another structure, it may mean that a structure is integrally formed on another structure, or that a structure is “directly” arranged on another structure, or that a structure is “indirectly” arranged on another structure through other structures.

The terms “one”, “a” and “said” are used to indicate the existence of one or more elements/components or the like; the terms “include” and “have” are used to indicate an open meaning of including and mean that there may be additional elements/components or the like in addition to the listed elements/components or the like. The terms “first” and “second” are only used as marks, without limiting the number of related objects.

White light devices are usually formed by connecting two or more light-emitting units with different colors in series. In some white light devices, the first electrode layer or the layer there below is/are not on the same plane. That is, they are in different regions, on different planes, and different regions have height difference. When the film is formed by evaporation deposition, the thickness of the multi-film layer structure deposited on the first electrode layer is inconsistent in different regions, especially in the transition region between two planes. A thickness distortion of an earlier deposited layer is greater in the transition region, and a structural distortion of an earlier deposited unit is greater, so the differences is obvious in the emission synthesis spectra of the upper unit and lower unit in the plane region and the transition region. The current-voltage characteristics and voltage-brightness-chromaticity are also different. For example, a turn-on voltage of an abnormal device in the transition region is lower than a turn-on voltage of a normal device in the plane region. In some cases, under a low driving voltage, only a later deposited unit of the abnormal device in the transition region emits light. Under a higher voltage, two units of the normal device in the plane region emit light at the same time. Thus, when the driving voltage changes from low to high, the color of the pixel emission changes greatly, thereby causing a color difference between high brightness and low brightness for the displayed image, and an abnormal gray-scale color point of the displayed picture.

For example, in the related art, a white pixel is composed of a blue light-emitting unit and a yellow light-emitting unit connected in series, where the yellow light-emitting unit is located on a side of the blue light-emitting unit close to the first electrode. In order to increase the light-emitting area, the substrate below the first electrode is provided with a pit, and the first electrode covers the pit. The yellow light-emitting unit and the blue light-emitting unit are sequentially arranged on the side of the first electrode away from the substrate. A charge generation layer is further arranged between the yellow light-emitting unit and the blue light-emitting unit. Due to the influence of the pit, when depositing the light-emitting film layer of the yellow light-emitting unit, the thickness of the film layer in the sidewall region of the pit is less than the thickness of the film layer in the middle region of the pit. The closer to the first electrode, the greater the difference in film layer thickness between the pit sidewall region and the normal region. Generally, the film layer thickness in the sidewall region of the pit corresponding to the blue light-emitting unit is greater than the film layer thickness in the sidewall region of the pit corresponding to the yellow light-emitting unit, while the film layer thickness in the middle region of the pit corresponding to the blue light-emitting unit is roughly equal to the film layer thickness in the middle region of the pit corresponding to the yellow light-emitting unit. Moreover, in the yellow light-emitting unit, the difference between the film layer thickness in the sidewall region of the pit and the film layer thickness in the middle region of the pit is greater, while in the blue light-emitting unit, the difference between the film layer thickness in the sidewall region of the pit and the film layer thickness in the middle region of the pit is smaller.

For this kind of white pixel, there may be many bad light-emitting phenomena when it emits light. For example, white pixels show different light-emitting spectra upon being driven under lower voltage and higher voltage.

In one case, the driving voltage becomes smaller since the film layer thickness in the sidewall region of the pit corresponding to the yellow light-emitting unit becomes thinner; and the exciton generated by carrier injection is severely quenched because the thickness of the yellow light-emitting unit in the sidewall region of the pit becomes thinner sharply, so that the part of the yellow light-emitting unit in the sidewall region does not emit light. Thus, when a driving voltage increased gradually is applied to the white pixel, at the lower voltage, the turn-on voltage of the light-emitting device in the sidewall region is lower than that in the normal region. When driven by this lower voltage, the normal region does not emit light, but the sidewall region emits blue light of the blue light-emitting unit. When the voltage is increased to exceed the turn-on voltage of the normal region, the blue light-emitting unit and the yellow light-emitting unit in the normal region emit light at the same time. Therefore, the overall performance is that the pixels emit blue light at lower voltage and emit white light at higher voltage.

In addition, in another case, the thickness in the sidewall region of the pit corresponding to the yellow light-emitting unit is reduced, and the turn-on voltage of the yellow light-emitting unit is reduced. At the lower voltage, the yellow light-emitting unit emits light before the blue light-emitting unit, so that yellow light is emitted. When the voltage is further increased, the blue light-emitting unit in the sidewall region also emits light; and further, the blue light-emitting unit and the yellow light-emitting unit in the normal region emit light at the same time. Therefore, the overall performance is that the pixels emit yellow light at the lower voltage and emit white light at the higher voltage. In this way, white pixels show different light-emitting spectra upon being driven by lower voltage and higher voltage.

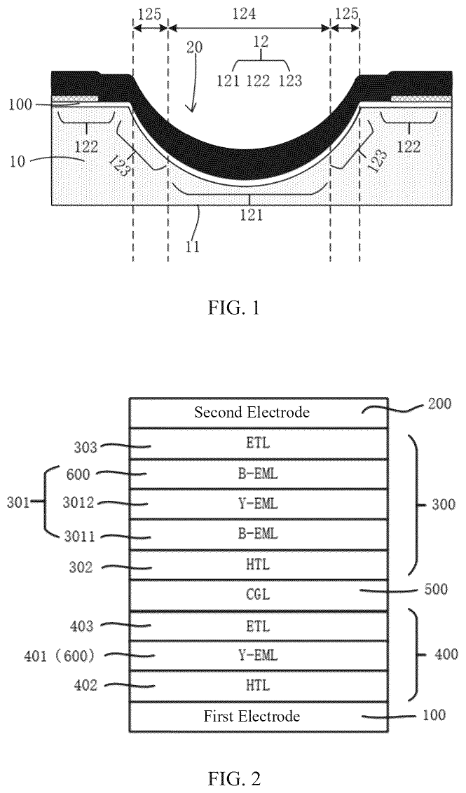

As shown in FIG. 1 and FIG. 2, the present disclosure provides the light-emitting device 20 including the substrate 10; and the first electrode 100, the light-emitting unit, and the second electrode 200 stacked in the direction away from the substrate 10; the light-emitting unit includes the plurality of light-emitting sub-units stacked in a direction perpendicular to the substrate 10 and the charge generation layer 500 located between adjacent light-emitting sub-units; among the plurality of light-emitting sub-units, the light-emitting sub-unit close to the second electrode 200 is the white light-emitting unit.

The light-emitting device 20 provided by the present disclosure includes the plurality of light-emitting sub-units, where the light-emitting sub-unit close to the second electrode 200 is the white light-emitting unit, so as to ensure that at least one light-emitting unit emits white light, which facilitates to mitigating the problem of the large light-emitting quality difference when the driving voltage of the light-emitting device 20 changes from low to high.

Hereinafter, the components of the light-emitting device 20 provided by the present disclosure will be described in detail with reference to the drawings and specific embodiments.

As shown in FIG. 1 and FIG. 2, the present disclosure provides the light-emitting device 20, which may be the white light device used in the display panel and may be used as the white pixel. The light-emitting device 20 includes the substrate 10; and the first electrode 100, the light-emitting unit and the second electrode 200 stacked in the direction away from the substrate.

In some embodiments of the present disclosure, the substrate 10 includes a first region 124 and a second region 125 located on the side of the first region 124 of the substrate 10, where part of the light-emitting unit is located in the first region 124 of the substrate 10, and part of the light-emitting unit is located in the second region 125 of the substrate 10. That is, when each film layer in the light-emitting unit is deposited and formed, the orthographic projection of the film layer on the substrate 10 is partially located in the first region 124 of the substrate 10, and partially located in the second region 125 of the substrate 10. In the present disclosure, the positional relationship between the first region 124 and the second region 125 of the substrate 10 is not particularly limited, and the number of the first region 124 and the second region 125 may be one, two or more, respectively.

In some embodiments of the present disclosure, the substrate 10 has the first surface 11 and the second surface 12 which are opposite to each other. The first surface 11 is the bottom surface, and at least part of the bottom surface is located on a same horizontal plane, which is taken as a reference plane. Different regions of the second surface 12 have different distances from the reference plane. For example, the first surface 11 includes the first sub-surface 121, the second sub-surface 122 and the transition surface 123 connecting the first sub-surface 121 and the second sub-surface 122. The distance between the first sub-surface 121 and the reference plane is less than the distance between the second sub-surface 122 and the reference plane. The transition surface 123 connects the first sub-surface 121 and the second sub-surface 122. The first sub-surface 121 and the second sub-surface 122 may be approximately parallel to the reference plane. In some embodiments, the first sub-surface 121 and the second sub-surface 122 may be planes or cambered surfaces, and when they are cambered surfaces, the corresponding arc radii of the cambered surfaces are relatively large, so that the cambered surfaces could be approximately parallel to the reference plane to some extent. In some embodiments, the first region 124 of the substrate 10 includes the first sub-surface 121 and does not include the transition surface 123 and the second sub-surface 122, and the second region 125 of the substrate 10 includes the transition surface 123 and does not include the first sub-surface 121 and the second sub-surface 122. The first region 124 of the substrate 10 may be a region containing the first sub-surface 121, and the second region 125 of the substrate 10 may be a region containing the transition surface 123. Further, in a specific embodiment, the first sub-surface 121 and the transition surface 123 of the substrate 10 form a groove on the substrate 10, and a cross section of the groove may be circular arc, inverted trapezoid, or the like.

Optionally, the first electrode 100 includes a first electrode material, which is preferably a material with a large work function that facilitates holes injection into the functional layer. Specific example of the first electrode material include metals such as nickel, platinum, vanadium, chromium, cop, zinc, gold, or their alloys; metal oxides such as zinc oxide, indium oxide, indium tin oxide (ITO) and indium zinc oxide (IZO); combined metals and oxides such as ZnO:Al or SnO2:Sb; or conductive polymers such as poly (3-methylthiophene), poly[3,4-(ethylene-1,2-dioxy) thiophene](PEDT), polypyrrole and polyaniline, but not limited thereto. It is preferable to include a transparent electrode containing indium tin oxide (ITO) as the first electrode 100. The first electrode 100 may serve as an anode of the light-emitting device 20.

Optionally, the second electrode 200 includes a second electrode material which is a material with a small work function that facilitates electrons injection into the functional layer. Specific examples of the second electrode material include: metals such as magnesium, calcium, sodium, potassium, titanium, indium, yttrium, lithium, gadolinium, aluminum, silver, tin, lead or their alloys; or multilayer materials such as LiF/Al, Liq/Al, LiO₂/Al, LiF/Ca, LiF/Al and BaF₂/Ca, but not limited thereto. It is preferable to include a metal electrode containing silver and magnesium as the second electrode 200. The second electrode 200 may serve as a cathode of the light-emitting device 20.

The plurality of light-emitting sub-units at least include the second light-emitting unit 400 and the first light-emitting unit 300 stacked in the direction away from the substrate 10, and the first light-emitting unit 300 is the white light-emitting unit. The charge generation layer 500 is arranged between the second light-emitting unit 400 and the first light-emitting unit 300. The charge generation layer 500 may include a hole generation layer and an electron generation layer, and the hole generation layer is arranged on a side of the electron generation layer away from the first electrode 100.

The thickness of the light-emitting unit located in the first region 124 of the substrate 10 is greater than the thickness of the light-emitting unit located in the second region 125 of the substrate 10. For example, the sum of the thicknesses of the first light-emitting unit 300, the charge generation layer 500 and the second light-emitting unit 400 located in the first region 124 of the substrate 10 is greater than the sum of the thicknesses of the first light-emitting unit 300, the charge generation layer 500 and the second light-emitting unit 400 located in the second region 125 of the substrate 10. For example, the first light-emitting unit 300, the charge generation layer 500 and the second light-emitting unit 400 all include a third region and a fourth region, where the third region is arranged corresponding to the first region 124 of the substrate 10 in the direction perpendicular to the substrate 10, and the fourth region is arranged corresponding to the second region 125 of the substrate 10 in the direction perpendicular to the substrate 10. The sum of the thicknesses of the third region of the first light-emitting unit 300, the charge generation layer 500 and the second light-emitting unit 400 is greater than the sum of the thicknesses of the fourth region of the first light-emitting unit 300, the charge generation layer 500 and the second light-emitting unit 400.

In some embodiments of the present disclosure, the thickness of the second light-emitting unit 400 located in the second region 125 of the substrate 10 is less than the thickness of the second light-emitting unit 400 located in the first region 124 of the substrate 10; the thickness of the first light-emitting unit 300 located in the second region 125 of the substrate 10 is less than or equal to the thickness of the first light-emitting unit 300 located in the first region 124. The thickness of the first light-emitting unit 300 located in the second region 125 of the substrate 10 is greater than the thickness of the second light-emitting unit 400 located in the second region 125 of the substrate 10.

In some embodiments of the present disclosure, the thickness of the first light-emitting unit 300 located in the second region 125 of the substrate 10 is greater than the thickness of the second light-emitting unit 400 located in the second region 125 of the substrate 10, and the difference in thickness is h1. That is, the thickness of the fourth region of the first light-emitting unit 300 is greater than the thickness of the fourth region of the second light-emitting unit 400, and the difference in thickness is h1.

The difference between the thickness of the first light-emitting unit 300 located in the first region 124 of the substrate 10 and the thickness of the second light-emitting unit 400 located in the first region 124 of the substrate 10 is h2, where h1>h2, and 0 μm≤h2≤0.5 μm. That is, the difference between the thickness of the fourth region of the first light-emitting unit 300 and the thickness of the fourth region of the second light-emitting unit 300 is h2. Further, the thickness of the third region of the second light-emitting unit 400 is greater than the thickness of the fourth region of the second light-emitting unit 400.

Among the first light-emitting unit 300 and the second light-emitting unit 400, the first light-emitting unit 300 may be the white light-emitting unit, or both of them may be white light-emitting units. In an embodiment, the white light-emitting unit may be a light-emitting unit including the yellow light-emitting layer (Y-EML) and the blue light-emitting layer (B-EML), or a light-emitting unit including the red light-emitting layer (H-EML), the green light-emitting layer (G-EML) and the blue light-emitting layer.

In the present disclosure, there may be various film layer structures included in the first light-emitting unit 300 and the second light-emitting unit 400, and the film layer structures in the first light-emitting unit 300 and the second light-emitting unit 400 will be described in detail with specific embodiments as follows.

As shown in FIG. 2 to FIG. 7, the first light-emitting unit 300 includes the first light-emitting layer 301, which includes the first light-emitting sub-layer 3011 and the second light-emitting sub-layer 3012 stacked in the direction away from the substrate 10; among the first light-emitting sub-layer 3011 and the second light-emitting sub-layer 3012, one is the blue light-emitting layer and the other is the yellow light-emitting layer.

In some embodiments of the present disclosure, the first light-emitting unit 300 further includes the first hole transport layer (HTL) 302 and the first electron transport layer (ETL) 303, where the first hole transport layer 302 is arranged between the charge generation layer 500 and the first light-emitting layer 301, and the first electron transport layer 303 is arranged between the second electrode 200 and the first light-emitting layer 301.

Optionally, the first light-emitting sub-layer 3011 and the second light-emitting sub-layer 3012 may be composed of the single light-emitting material, or may include the host material and the guest material. Optionally, in an embodiment, the first light-emitting sub-layer 3011 and/or the second light-emitting sub-layer 3012 are composed of the single light-emitting material. In this embodiment, the first light-emitting sub-layer 3011 and the second light-emitting sub-layer 3012 may be made into thin film layers, for example, the thickness of each of the first light-emitting sub-layer 3011 or the second light-emitting sub-layer 3012 may not exceed 10 nm. In this way, it is helpful to reduce the difference between the thickness of the fourth region in the first light-emitting unit 300 and the thickness of the fourth region in the second light-emitting unit 400, thus mitigating the light-emitting difference between the fourth region in the first light-emitting unit 300 and the fourth region in the second light-emitting unit 400 to some extent.

In another embodiment, the first light-emitting sub-layer 3011 and the second light-emitting sub-layer 3012 are composed of the host material and the guest material. The holes injected into the first light-emitting sub-layer 3011 and the second light-emitting sub-layer 3012 and the electrons injected into the first light-emitting sub-layer 3011 and the second light-emitting sub-layer 3012 could recombine in the first light-emitting sub-layer 3011 and the second light-emitting sub-layer 3012 to form excitons, the excitons transfer energy to the host material, and the host material transfers energy to the guest material, thereby causing the guest material to emit light.

The host materials of the first light-emitting sub-layer 3011 and the second light-emitting sub-layer 3012 may be metal chelating compounds, stilbene derivatives, aromatic amine derivatives, dibenzofuran derivatives or other types of materials, which are not particularly limited in the present disclosure.

The guest materials of the first light-emitting sub-layer 3011 and the second light-emitting sub-layer 3012 may be compounds with condensed aryl rings or their derivatives, compounds with heteroaryl rings or their derivatives, aromatic amine derivatives or other materials, which are not particularly limited in the present disclosure.

In some embodiments of the present disclosure, the first light-emitting sub-layer 3011 is the blue light-emitting layer, the second light-emitting sub-layer 3012 is the yellow light-emitting layer, and the material of the first light-emitting sub-layer 3011 is the phosphorescent light-emitting material; or the first light-emitting sub-layer 3011 is the yellow light-emitting layer, the second light-emitting sub-layer 3012 is the blue light-emitting layer, and the material of the second light-emitting sub-layer 3012 is preferably the fluorescent light-emitting material.

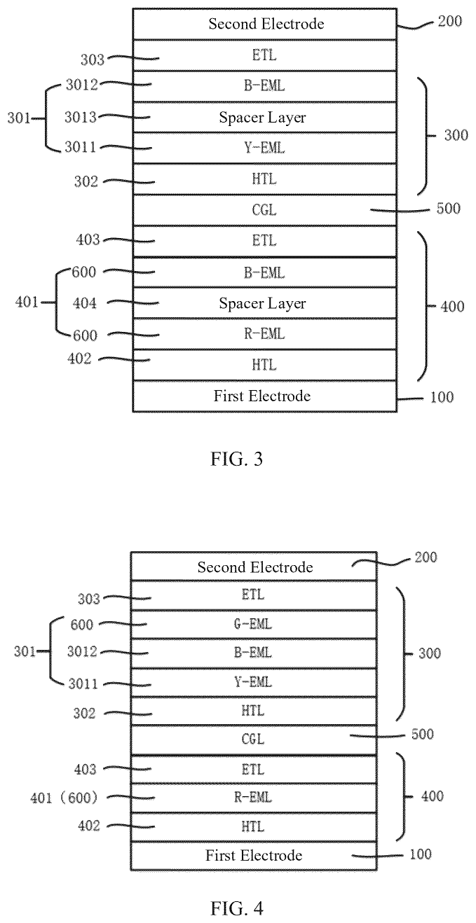

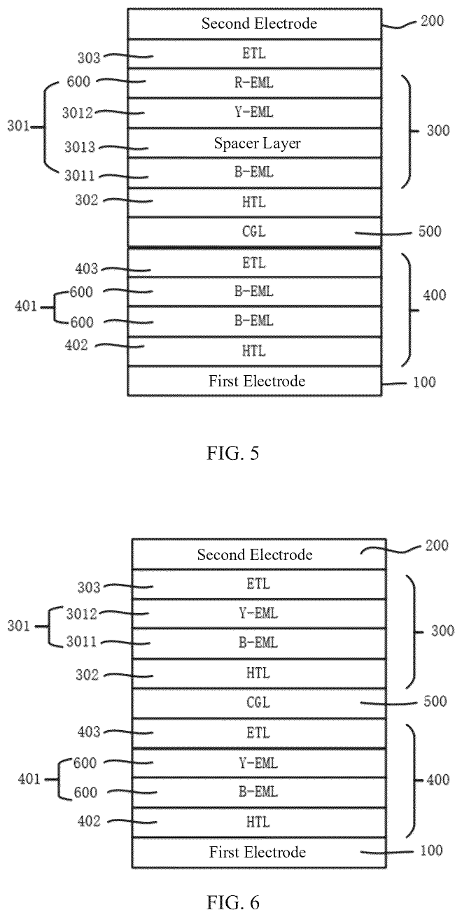

As shown in FIG. 3 and FIG. 5, further, the first light-emitting layer 301 further includes the first spacer layer 3013, the material of the first spacer layer 3013 may be an organic material or an inorganic material, and the first spacer layer is used for adjusting a carrier transmission between the first light-emitting sub-layer 3011 and the second light-emitting sub-layer 3012. The first spacer layer 3013 is arranged between the first light-emitting sub-layer 3011 and the second light-emitting sub-layer 3012.

The second light-emitting unit 400 includes a second light-emitting layer 401. As shown in FIG. 2 to FIG. 7, in order to further adjust the white light characteristics of the light-emitting device 20, the first light-emitting layer 301 or/and the second light-emitting layer 401 includes at least one optical adjustment layer 600 for adjusting the light-emitting characteristics of the light-emitting unit. The optical adjustment layer 600 includes at least one of the blue light-emitting layer, the yellow light-emitting layer, the green light-emitting layer or the red light-emitting layer, and may be specifically selected according to the light-emitting characteristic of the first light-emitting sub-layer 3011 and the second light-emitting sub-layer 3012. For example, if the green light in the light formed by the first light-emitting sub-layer 3011 and the second light-emitting sub-layer 3012 is insufficient, the optical adjustment layer 600 may be the green light-emitting layer. If the red light in the light formed by the first light-emitting sub-layer 3011 and the second light-emitting sub-layer 3012 is insufficient, the optical adjustment layer 600 may be the red light-emitting layer. If the blue light in the light formed by the first light-emitting sub-layer 3011 and the second light-emitting sub-layer 3012 is insufficient, the optical adjustment layer 600 may be the blue light-emitting layer. The optical adjustment layer 600 may be composed of a single light-emitting material, and may also include a host material and a guest material, which may be adjusted according to actual requirements.

Next, the arranging scheme of the optical adjustment layer 600 will be exemplified in combination with different embodiments.

As shown in FIG. 2 and FIG. 4, in an embodiment of the present disclosure, one of the first light-emitting sub-layer 3011 and the second light-emitting sub-layer 3012 is the blue light-emitting layer, and the other of the first light-emitting sub-layer 3011 and the second light-emitting sub-layer 3012 is the yellow light-emitting layer. The first light-emitting layer 301 further includes one optical adjustment layer 600, and the optical adjustment layer 600 of the first light-emitting layer 301 is located on the side of the second light-emitting sub-layer 3012 away from the substrate 10. The second light-emitting layer 401 includes one optical adjustment layer 600, and the optical adjustment layer 600 of the second light-emitting layer 401 is the yellow light-emitting layer or the red light-emitting layer.

As shown in FIG. 2, in some embodiments, the optical adjustment layer 600 in the second light-emitting layer 401 is the yellow light-emitting layer, and the optical adjustment layer 600 in the first light-emitting layer 301 is the blue light-emitting layer. The blue optical adjustment layer 600 in the first light-emitting layer 301 and the yellow optical adjustment layer 600 in the second light-emitting layer 401 can complete the blue light and yellow light compensation of the light-emitting unit.

Further, in some embodiments, one of the first light-emitting sub-layer 3011 and the second light-emitting sub-layer 3012 is the blue light-emitting layer, the optical adjustment layer 600 in the first light-emitting layer 301 is the blue light-emitting layer, and the light-emitting materials of the two blue light-emitting layers may be the same or different. Optionally, the materials are different, that is, the materials are selected from different blue light-emitting materials. The blue spectrum emitted by different blue light-emitting materials may be different, so it is helpful to adjust the white color gamut. Similarly, the other of the first light-emitting sub-layer 3011 and the second light-emitting sub-layer 3012 is the yellow light-emitting layer, the optical adjustment layer 600 in the second light-emitting layer 401 is the yellow light-emitting layer, and the light-emitting materials of the two yellow light-emitting layers may be the same or different. Optionally, the materials are different, that is, they are selected from different yellow light-emitting materials. The yellow spectrum emitted by different yellow light-emitting materials may be different, so it is helpful to adjust the white color gamut.

Further, in some embodiments, the thickness of the yellow light-emitting layer in the first light-emitting sub-layer 3011 and the second light-emitting sub-layer 3012 is relatively thin, which facilitates to reducing the difference between the thickness of the fourth region in the first light-emitting unit 300 and the thickness of the fourth region in the second light-emitting unit 400, thus mitigating the light-emitting difference between the fourth region in the first light-emitting unit 300 and the fourth region in the second light-emitting unit 400 to some extent. For example, even at the low voltage, the driving voltage of the fourth region of in first light-emitting unit 300 can be reached to drive it to emit light, which facilitates to reducing the difference in emission spectrum of the light-emitting device 20 driven at the lower voltage and the higher voltage.

Specifically, the thickness of the yellow light-emitting layer in the first light-emitting sub-layer 3011 and the second light-emitting sub-layer 3012 may be 0.1 nm to 5 nm, which may be 0.1 nm, 0.5 nm, 1 nm, 1.2 nm, 1.4 nm, 1.6 nm, 1.8 nm, 2 nm, 2.2 nm, 2.4 nm, 2.6 nm, 2.8 nm, 3 nm, 3.2 nm, 3.4 nm, 3.6 nm, 3.8 nm, 4 nm, 4.2 nm, 4.4 nm, 4.6 nm, 4.8 nm or 5 nm, but it is not limited thereto.

In addition, in this embodiment, the yellow light-emitting layer in the first light-emitting sub-layer 3011 and the second light-emitting sub-layer 3012 may be composed of the single light-emitting material, that is, the light-emitting material of the yellow light-emitting layer in the first light-emitting sub-layer 3011 and the second light-emitting sub-layer 3012 is non-doped material. Non-doped material is conducive to the formation of thinner light-emitting films in process, thus reducing the process difficulty and improving the production yield of devices.

In some embodiments, except for the yellow light-emitting layer in the first light-emitting sub-layer 3011 and the second light-emitting sub-layer 3012, the thickness of other light-emitting layers may not be limited, which may be 15 nm to 30 nm or the like.

Further, the first light-emitting sub-layer 3011 is the blue light-emitting layer, and the second light-emitting sub-layer 3012 is the yellow light-emitting layer. The optical adjustment layer 600 in the first light-emitting layer 301 is located on the side of the second light-emitting sub-layer 3012 away from the substrate 10.

As shown in FIG. 4, in another embodiment of the present disclosure, the optical adjustment layer 600 of the second light-emitting layer 401 is the red light-emitting layer, and the optical adjustment layer 600 of the first light-emitting layer 301 is the green light-emitting layer. In this embodiment, the green optical adjustment layer 600 in the first light-emitting layer 301 and the red optical adjustment layer 600 in the second light-emitting layer 401 can complete the green light compensation and red light compensation of the light-emitting unit.

Further, in this embodiment, the thickness of each film layer is not particularly limited. It may be 15 nm to 30 nm, or the like. Optionally, the thickness of the yellow light-emitting layer in the first light-emitting sub-layer 3011 and the second light-emitting sub-layer 3012 is relatively thin, which facilitates to reducing the difference between the thickness of the fourth region in the first light-emitting unit 300 and the thickness of the fourth region in the second light-emitting unit 400, thus mitigating the light-emitting difference between the fourth region in the first light-emitting unit 300 and the fourth region in the second light-emitting unit 400 to some extent.

Specifically, the thickness of the yellow light-emitting layer in the first light-emitting sub-layer 3011 and the second light-emitting sub-layer 3012 is 0.1 nm to 5 nm, which may be 0.1 nm, 0.5 nm, 1 nm, 1.2 nm, 1.4 nm, 1.6 nm, 1.8 nm, 2 nm, 2.2 nm, 2.4 nm, 2.6 nm, 2.8 nm, 3 nm, 3.2 nm, 3.4 nm, 3.6 nm, 3.8 nm, 4 nm, 4.2 nm, 4.4 nm, 4.6 nm, 4.8 nm or 5 nm, but it is not limited thereto.

In addition, in some embodiments, the yellow light-emitting layer in the first light-emitting sub-layer 3011 and the second light-emitting sub-layer 3012 may be composed of the single light-emitting material, that is, the light-emitting material of the yellow light-emitting layer in the first light-emitting sub-layer 3011 and the second light-emitting sub-layer 3012 is non-doped material. Non-doped material is conducive to the formation of thinner light-emitting films in process, thus reducing the process difficulty and improving the production yield of devices.

Further, in some embodiments, the first light-emitting sub-layer 3011 is the yellow light-emitting layer, and the second light-emitting sub-layer 3012 is the blue light-emitting layer. The optical adjustment layer 600 in the first light-emitting layer 301 is arranged on the side of the second light-emitting sub-layer 3012 away from the substrate 10.

As shown in FIG. 3, in another embodiment of the present disclosure, the second light-emitting layer 401 includes two optical adjustment layers 600, in which one optical adjustment layer 600 is the blue light-emitting layer and the other optical adjustment layer 600 is the red light-emitting layer. In some embodiments, the blue optical adjustment layer 600 and the red optical adjustment layer 600 in the second light-emitting layer 401 can complete the blue light compensation and red light compensation of the light-emitting unit.

Further, in some embodiments, one of the first light-emitting sub-layer 3011 and the second light-emitting sub-layer 3012 is the blue light-emitting layer, one optical adjustment layer 600 in the second light-emitting layer 401 is the blue light-emitting layer, and the light-emitting materials of the two blue light-emitting layers may be the same or different. Optionally, the materials are different, that is, they are selected from different blue light-emitting materials. The blue spectrum emitted by different blue light-emitting materials may be different, so it is helpful to adjust the white color gamut.

In some embodiments, the material of the blue light-emitting layer may be fluorescent light-emitting material or phosphorescent light-emitting material, and the position of the blue light-emitting layer may be different for different types of light-emitting materials. For example, the first light-emitting sub-layer 3011 is the yellow light-emitting layer, the second light-emitting sub-layer 3012 is the blue light-emitting layer, and the material of the second light-emitting sub-layer 3012 is optionally the fluorescent light-emitting material. The first light-emitting layer 301 further includes the first spacer layer 3013, which is arranged between the first light-emitting sub-layer 3011 and the second light-emitting sub-layer 3012. In the two optical adjustment layers 600 of the second light-emitting layer 401, the blue light-emitting layer is located on the side of the red light-emitting layer away from the substrate 10, and the material of the blue light-emitting layer is optionally the fluorescent light-emitting material; the second light-emitting layer 401 further includes the second spacer layer 404, which is arranged between the two optical adjustment layers 600 of the second light-emitting layer 401.

Further, in some embodiments, the thickness of each film layer is not particularly limited. It may be 15 nm to 30 nm, or the like. Optionally, the thickness of the first light-emitting sub-layer 3011 of the first light-emitting unit 300 is relatively thin, which facilitates to reducing the difference between the thickness of the fourth region in the first light-emitting unit 300 and the thickness of the fourth region in the second light-emitting unit 400, thus mitigating the light-emitting difference between the fourth region in the first light-emitting unit 300 and the fourth region in the second light-emitting unit 400 to some extent. Specifically, the thickness of the first light-emitting sub-layer 3011 may be less than 10 nm, or less than 5 nm, or 0.1 nm to 5 nm, for example, which may be 0.1 nm, 0.5 nm, 1 nm, 1.2 nm, 1.4 nm, 1.6 nm, 1.8 nm, 2 nm, 2.2 nm, 2.4 nm, 2.6 nm, 2.8 nm, 3 nm, 3.2 nm, 3.4 nm, 3.6 nm, 3.8 nm, 4 nm, 4.2 nm, 4.4 nm, 4.6 nm, 4.8 nm or 5 nm, but it is not limited thereto.

As shown in FIG. 5, in another embodiment of the present disclosure, the first light-emitting layer 301 further includes one optical adjustment layer 600, and the optical adjustment layer 600 in the first light-emitting layer 301 is the red light-emitting layer; the second light-emitting layer 401 includes two optical adjustment layers 600, both of which are blue light-emitting layers. In this embodiment, the red optical adjustment layer 600 in the first light-emitting layer 301 and the two blue red optical adjustment layers 600 in the second light-emitting layer 401 can complete the red light and blue light compensation of the light-emitting unit.

The materials of the two blue optical adjustment layers 600 in the second light-emitting layer 401 may be the same or different. Optionally, the materials are different, that is, the materials are selected from different blue light-emitting materials. The blue spectrum emitted by different blue light-emitting materials may be different, so it is helpful to adjust the white color gamut. In addition, by selecting the emission wavelengths of two blue light-emitting layers with different materials in the second light-emitting layer 401, it is possible to mitigate both high color temperature and blue-light damage.

Further, in some embodiments, the thickness of each film layer is not particularly limited. It may be 15 nm to 30 nm, or the like. Optionally, the thickness of the yellow light-emitting layer in the first light-emitting sub-layer 3011 and the second light-emitting sub-layer 3012 is relatively thin, and the thickness range can refer to any of the above-mentioned embodiments, which will not be described in detail here.

Specifically, the first light-emitting sub-layer 3011 is the blue light-emitting layer, and the second light-emitting sub-layer 3012 is the yellow light-emitting layer. The first light-emitting layer 301 further includes the first spacer layer 3013, which is arranged between the first light-emitting sub-layer 3011 and the second light-emitting sub-layer 3012. The optical adjustment layer 600 in the first light-emitting layer 301 is arranged on the side of the second light-emitting sub-layer 3012 away from the substrate 10.

As shown in FIG. 6, in an embodiment of the present disclosure, the second light-emitting unit 400 includes the second light-emitting layer 401, and the second light-emitting layer 401 includes two optical adjustment layers 600; where the two optical adjustment layers 600 are the blue light-emitting layer and the yellow light-emitting layer stacked in the direction away from the substrate.

In some embodiments, the first light-emitting unit 300 includes the first light-emitting layer 301, which includes the first light-emitting sub-layer 3011 and the second light-emitting sub-layer 3012 stacked in the direction away from the substrate 10. Among the first light-emitting sub-layer 3011 and the second light-emitting sub-layer 3012, the first light-emitting sub-layer 3011 is the blue light-emitting layer, and the second light-emitting sub-layer 3012 is the yellow light-emitting layer.

The blue light-emitting layer in the first light-emitting unit 300 and the second light-emitting layer 401 may be made from phosphorescent light-emitting material or fluorescent light-emitting material, and the positional relationship of each light-emitting layer may be different for different types of light-emitting materials. For example, the first light-emitting sub-layer 3011 is the blue light-emitting layer and the second light-emitting sub-layer 3012 is the yellow light-emitting layer. In some embodiments, the material of the blue light-emitting layer is the phosphorescent material.

Further, the optical adjustment layers 600 (blue light-emitting layer) in the first light-emitting sub-layer 3011 and the second light-emitting layer 401 may be made from the same or different blue light-emitting materials and, preferably, made from different blue light-emitting materials. The optical adjustment layers 600 (yellow light-emitting layer) in the second light-emitting sub-layer 3012 and the second light-emitting layer 401 may be made from the same or different yellow light-emitting materials and, preferably, made from different yellow light-emitting materials.

Similar to the above-mentioned embodiments, the yellow light-emitting layer in the first light-emitting layer 301 may be set to a thinner thickness, where the principle, specific thickness range and material selection can refer to any of the above-mentioned embodiments.

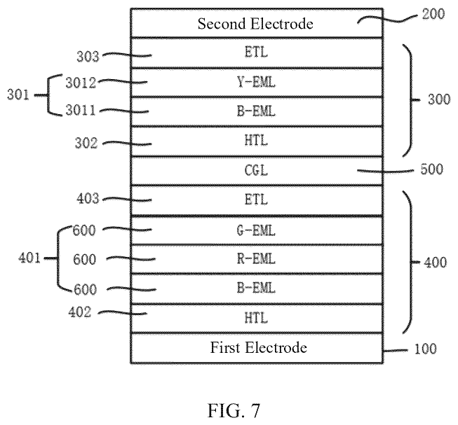

As shown in FIG. 7, in another embodiment of the present disclosure, the second light-emitting unit 400 includes the second light-emitting layer 401, and the second light-emitting layer 401 includes three optical adjustment layers 600. The three optical adjustment layer 600 are the blue light-emitting layer, the red light-emitting layer and the green light-emitting layer stacked in the direction away from the substrate 10.

In some embodiments, the first light-emitting unit 300 includes the first light-emitting layer 301, which includes the first light-emitting sub-layer 3011 and the second light-emitting sub-layer 3012 stacked in the direction away from the substrate 10. The first light-emitting sub-layer 3011 is the blue light-emitting layer, and the second light-emitting sub-layer 3012 is the yellow light-emitting layer.

Further, the optical adjustment layer 600s (blue light-emitting layer) in the first light-emitting sub-layer 3011 and the second light-emitting layer 401 may be made from the same or different blue light-emitting materials and, preferably, made from different blue light-emitting materials.

The second light-emitting sub-layer 3012 in the first light-emitting layer 301 may be set to a relatively thin thickness, for example, its thickness may be 1 nm to 10 nm, such as 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm or 10 nm, but it is not limited thereto. The second light-emitting sub-layer 3012 may be composed of a single light-emitting material, that is, a non-doped material. Non-doped materials are conducive to the formation of thinner light-emitting films in process, thus reducing the process difficulty and improving the production yield of devices.

As shown in FIG. 6 and FIG. 7, in the present disclosure, the first light-emitting unit 300 and the second light-emitting unit 400 may both be the white light-emitting unit. In such embodiments, even if only a partial region of one light-emitting unit emits light at low voltage, it can be ensure that the light-emitting device 20 can emit white light.

As shown in FIG. 2 to FIG. 7, in some embodiments of the present disclosure, the second light-emitting unit 400 further includes the second hole transport layer 402 and the second electron transport layer 403, where the second hole transport layer 402 is arranged between the first electrode 100 and the second light-emitting layer 401, and the second electron transport layer 403 is arranged between the second light-emitting layer 401 and the charge generation layer 500.

The first hole transport layer 302 and the second hole transport layer 402 may include one or more hole transport material(s), and the hole transport materials may be selected from carbazole polymers, carbazole-linked triarylamines, or other types of compounds, which are not particularly limited in the present disclosure.

The first electron transport layer 303 and the second electron transport layer 403 may include one or more electron transport material(s), and the electron transport materials may be selected from benzimidazole derivatives, oxadiazole derivatives, quinoxaline derivatives, or other electron transport materials, which are not particularly limited in the present disclosure.

In the present disclosure, when the blue light-emitting layer, the green light-emitting layer and the red light-emitting layer are composed of the host material and the guest material, the host material of the blue light-emitting layer may be selected from anthracene derivatives ADN, MADN, etc.; and the guest material of the blue light-emitting layer may be selected from pyrene derivatives, fluorene derivatives, perylene derivatives, styrylamine derivatives, metal complexes, etc., such as TBPe, BDAVBi, DPAVBi, FIrpic, and the like. The host material of the green light-emitting layer may be selected from coumarin dye, quinacridine copper derivatives, polycyclic aromatic hydrocarbons, diamine anthracene derivatives, carbazole derivatives, such as DMQA, BA-NPB, Alq3, and the like; and the guest material thereof may be metal complexes, etc., such as Ir(ppy)3, Ir(ppy)2(acac), and the like. The host material of the red light-emitting layer may be selected from DCM series materials, such as DCM, DCJTB, DCJTI, etc., and the guest material thereof may be metal complexes, such as Ir(piq)2(acac), PtOEP, Ir(btp)2 (acac), and the like, but is not limited thereto.

The present disclosure further provides the display panel, including the light-emitting device 20 according to any of the above embodiments. The display panel includes a base substrate and a driving circuit layer arranged on one side of the base substrate, where the driving circuit layer may include the substrate 10 of the light-emitting device 20.

It should be understood that the present disclosure is not limited to the detailed structure and arrangement of components set forth in this specification. The present disclosure can be embodied, realized and carried out in various ways. The foregoing variations and modifications fall within the scope of the present disclosure. It should be understood that the present disclosure disclosed and defined in this specification extends to all alternative combinations of two or more individual features mentioned or obvious in the text and/or the drawings. All these different combinations constitute various alternative aspects of the present disclosure. The embodiments of this specification illustrate the best modes known for carrying out the present disclosure, and will enable those skilled in the art to make use of the present disclosure.

1. A light-emitting device, comprising a substrate, and a first electrode, a light-emitting unit and a second electrode stacked in a direction away from the substrate;
wherein, the light-emitting unit comprises a plurality of light-emitting sub-units stacked in a direction perpendicular to the substrate and a charge generation layer located between adjacent light-emitting sub-units; and
among the plurality of light-emitting sub-units, the light-emitting sub-unit close to the second electrode is a white light-emitting unit.

2. The light-emitting device according to claim 1, wherein the plurality of light-emitting sub-units at least comprise a second light-emitting unit and a first light-emitting unit stacked in the direction away from the substrate, and the first light-emitting unit is the white light-emitting unit.

3. The light-emitting device according to claim 2, wherein the first light-emitting unit comprises a first light-emitting layer, and the first light-emitting layer comprises a first light-emitting sub-layer and a second light-emitting sub-layer stacked in the direction away from the substrate;
one of the first light-emitting sub-layer and the second light-emitting sub-layer is a blue light-emitting layer and another one of the first light-emitting sub-layer and the second light-emitting sub-layer is a yellow light-emitting layer.

4. The light-emitting device according to claim 3, wherein the first light-emitting sub-layer is the blue light-emitting layer, the second light-emitting sub-layer is the yellow light-emitting layer, and a material of the first light-emitting sub-layer is a phosphorescent light-emitting material; or
the first light-emitting sub-layer is the yellow light-emitting layer, the second light-emitting sub-layer is the blue light-emitting layer, and a material of the second light-emitting sub-layer is a fluorescent light-emitting material.

5. The light-emitting device according to claim 3, wherein the first light-emitting layer further comprises a first spacer layer, and the first spacer layer is arranged between the first light-emitting sub-layer and the second light-emitting sub-layer.

6. The light-emitting device according to claim 3, wherein the second light-emitting unit comprises a second light-emitting layer, the first light-emitting layer and/or the second light-emitting layer comprise at least one optical adjustment layer, and the optical adjustment layer is configured to adjust a light-emitting characteristic of the light-emitting unit.

7. The light-emitting device according to claim 6, wherein the optical adjustment layer comprises at least one of a blue light-emitting layer, a yellow light-emitting layer, a green light-emitting layer or a red light-emitting layer.

8. The light-emitting device according to claim 6, wherein the first light-emitting layer further comprises one optical adjustment layer, and the optical adjustment layer of the first light-emitting layer is located on a side of the second light-emitting sub-layer away from the substrate; and
the second light-emitting layer comprises one optical adjustment layer, and the optical adjustment layer of the second light-emitting layer is a yellow light-emitting layer or a red light-emitting layer.

9. The light-emitting device according to claim 8, wherein, when the optical adjustment layer of the second light-emitting layer is the yellow light-emitting layer, the first light-emitting sub-layer is the blue light-emitting layer, the second light-emitting sub-layer is the yellow light-emitting layer, and the optical adjustment layer of the first light-emitting layer is the blue light-emitting layer.

10. The light-emitting device according to claim 8, wherein, when the optical adjustment layer of the second light-emitting layer is the red light-emitting layer, the first light-emitting sub-layer is the yellow light-emitting layer, the second light-emitting sub-layer is the blue light-emitting layer, and the optical adjustment layer of the first light-emitting layer is the green light-emitting layer.

11. The light-emitting device according to claim 6, wherein the second light-emitting layer comprises two optical adjustment layers, one of the two optical adjustment layers of the second light-emitting layer is a blue light-emitting layer and another one of the two optical adjustment layers of the second light-emitting layer is a red light-emitting layer, wherein the blue light-emitting layer is located on a side of the red light-emitting layer away from the substrate, and a material of the blue light-emitting layer is the fluorescent light-emitting material.

12. The light-emitting device according to claim 11, wherein the first light-emitting sub-layer is the yellow light-emitting layer, the second light-emitting sub-layer is the blue light-emitting layer, and a material of the second light-emitting sub-layer is the fluorescent light-emitting material;
the first light-emitting layer further comprises a first spacer layer, wherein the first spacer layer is arranged between the first light-emitting sub-layer and the second light-emitting sub-layer; and
the second light-emitting layer further comprises a second spacer layer, wherein the second spacer layer is arranged between the two optical adjustment layers of the second light-emitting layer.

13. The light-emitting device according to claim 6, wherein the first light-emitting layer further comprises one optical adjustment layer, and the optical adjustment layer of the first light-emitting layer is a red light-emitting layer located on a side of the second light-emitting sub-layer away from the substrate; and
the second light-emitting layer comprises two optical adjustment layers, and the two optical adjustment layers of the second light-emitting layer both are blue light-emitting layers.

14. The light-emitting device according to claim 13, wherein the first light-emitting sub-layer is the blue light-emitting layer, and the second light-emitting sub-layer is the yellow light-emitting layer;
the first light-emitting layer further comprises a first spacer layer, wherein the first spacer layer is arranged between the first light-emitting sub-layer and the second light-emitting sub-layer, and the optical adjustment layer of the first light-emitting unit is arranged on the side of the second light-emitting sub-layer away from the substrate.

15. The light-emitting device according to claim 6, wherein, when the first light-emitting sub-layer is the blue light-emitting layer and the second light-emitting sub-layer is the yellow light-emitting layer, the second light-emitting layer comprises two optical adjustment layers, and the two optical adjustment layers are a blue light-emitting layer and a yellow light-emitting layer stacked in the direction away from the substrate.

16. The light-emitting device according to claim 6, wherein, when the first light-emitting sub-layer is the blue light-emitting layer and the second light-emitting sub-layer is the yellow light-emitting layer, the second light-emitting layer comprises three optical adjustment layers;
wherein, the three optical adjustment layers are a blue light-emitting layer, a red light-emitting layer and a green light-emitting layer stacked in the direction away from the substrate.

17. The light-emitting device according to claim 1, wherein the substrate comprises a first region and a second region located on a side of the first region, a thickness of a light-emitting unit located in the first region is greater than a thickness of a light-emitting unit located in the second region; and
the plurality of light-emitting sub-units at least comprise a second light-emitting unit and a first light-emitting unit stacked in the direction away from the substrate, a thickness of the second light-emitting unit located in the second region is less than a thickness of the second light-emitting unit located in the first region;
a thickness of the first light-emitting unit located in the second region is less than or equal to a thickness of the first light-emitting unit located in the first region; and
the thickness of the first light-emitting unit located in the second region of the substrate is greater than the thickness of the second light-emitting unit located in the second region of the substrate.

18. The light-emitting device according to claim 3, wherein the thickness of the yellow light-emitting layer of the first light-emitting layer is 0.1 nm to 5 nm.

19. A display panel, comprising the light-emitting device according to claim 1.
